(19) United States
(12) Patent Application Publication
(10) Pub. No.: US 2014/0008710 A1
(43) Pub. Date: Jan. 9, 2014

(54) Metal/Semiconductor Compound Thin Film and a DRAM Storage Cell and Method of Making

(71) Applicants: Dongping Wu, Shanghai (CN); Shili Zhang, Shanghai (CN); Zhiwei Zhu, Shanghai (CN); Wei Zhang, Shanghai (CN)

(72) Inventors: Dongping Wu, Shanghai (CN); Shili Zhang, Shanghai (CN); Zhiwei Zhu, Shanghai (CN); Wei Zhang, Shanghai (CN)

(73) Assignee: FUDAN UNIVERSITY, Shanghai (CN)

(21) Appl. No.: 13/394,303

(22) PCT Filed: Sep. 28, 2011
(86) PCT No.: PCT/CN11/80285

§ 371 Date: Mar. 5, 2012

(30) Foreign Application Priority Data
Mar. 17, 2011 (CN) 201110063882.2

(51) Int. Cl. H01L 29/49; H01L 27/108

(52) U.S. Cl. CPC H01L 29/4933; H01L 27/108; H01L 27/10844
USPC 257/296; 257/755; 438/239; 438/155

(57) ABSTRACT

A metal-semiconductor-compound thin film is disclosed, which is formed between a semiconductor layer and a polycrystalline semiconductor layer, the metal-semiconductor-compound thin film having a thickness of about 2˜5 nm, so as to improve a contact between the semiconductor layer and the polycrystalline semiconductor layer. A DRAM storage cell is also disclosed. A metal-semiconductor-compound thin film having a thickness of about 2-5 nm is added between a drain region of a MOS transistor and a polycrystalline semiconductor buffer layer in the DRAM storage cell, so as to enhance read/write speed of the transistor of the DRAM storage cell while preventing excessive increase in leakage current between the drain region and a semiconductor substrate. A method for making a DRAM storage cell is also disclosed. A DRAM storage cell made using the method has a metal-semiconductor-compound thin film, with a thickness controlled at about 2˜5 nm, formed between a drain region of its MOS transitor and a polycrystalline semiconductor buffer layer, so as to enhance the performance of the DRAM storage cell.

### TECHNOLOGICAL FIELD

The present invention is related to microelectronic devices, and more particularly to a metal-semiconductor-compound thin film and a DRAM storage cell and method of making.

### BACKGROUND

Metal/semiconductor compound thin films have been widely used as metal electrodes to form metal-semiconductor contacts with silicon, germanium or silicon-germanium semiconductors for the source/drain and gate of metal-oxide-semiconductor field effect transistors (MOSFET).

From serving as reliable contacts for simple diodes in the beginning to using self-aligned metal/semiconductor compound thin film (salicide) forming processes to form low-resistance source/drain contacts and low-sheet-resistance gate electrodes in MOSFETs nowadays, metal/semiconductor compound thin films have played very important roles in the miniaturization of CMOS device sizes and the enhancement of device performance. As semiconductor fabrication technologies continue to improve, metal/semiconductor compound thin films have evolved from the earlier titanium silicide (TiSi₂), cobalt silicide (CoSi₂) to today's main stream nickel silicide (NiSi) or platinum incorporated nickel silicide (Ni(Pt)Si.

Also, as device sizes continue to shrink, metal/semiconductor compound thin films are required to be thinner and thinner. This is particularly obvious in dynamic random access memories (DRAM).

A DRAM is typically comprised of many basic storage cells arranged in rows and columns. Each storage cell includes a MOS transistor and a capacitor. The source region of the MOS transistor is coupled to a bit line, the gate of the MOS transistor is coupled to a word line, and the drain region of the MOS transistor is coupled to the capacitor via a buffer layer, where the buffer layer can be a highly doped polysilicon layer, and the capacitor can be a metal-insulator-metal (MIM) capacitor. The reason for adding the highly-doped polysilicon layer between the drain and the capacitor is that leakage current increases at the P-N junction formed between the drain and a silicon substrate (drain P-N junction) when a metal electrode of the MIM capacitor contacts the silicon substrate directly, degrading the charge-retention capability of the DRAM cell. By adding the highly-doped polysilicon layer, excessive increase in the drain P-N junction leakage current can be avoided.

However, because the drain region is made of silicon, contact resistance between silicon and polysilicon can be very large. Furthermore, a native oxide layer is usually formed on the silicon surface, which further increase the contact resistance between silicon and polysilicon, causing the transistor to have low read/write speed.

In a current technique to increase the read/write speed of the transistor, a metal/semiconductor compound thin film is formed at the drain region. The drain region is thus coupled to the polysilicon via the metal-semiconductor-compound thin film, so that the contact resistance between the drain region and the polysilicon is largely decreased, and the transistor read/write speed is enhanced.

However, after forming the metal-semiconductor-compound thin film at the drain region, the resistance of the P-N junction between the drain region and the semiconductor substrate is decreased as a result, causing the leakage current of the P-N junction to increase, making it easier for the capacitor to lose its stored charges. Thus, the DRAM needs to be refreshed frequently. Moreover, the thicker the metal-semiconductor-compound thin film, the less the storage capacity of the capacitor.

Therefore, in order to maintain the storage capacity of the capacitor while increasing the read/write speed of the transistor, the metal-semiconductor-compound thin film is desired to be thinner.

Currently, there are several ways of forming metal-semiconductor-compound thin films, as discussed below.

1) Titanium Silicide Process

In the titanium silicide process, metal titanium is deposited on a silicon wafer. A first annealing at a relatively low temperature is conducted subsequently to obtain a high resistance intermediate metastable phase C49. A second annealing at a slightly higher temperature is conducted to cause the C49 to phase transit into a needed final low resistance C54 phase (stable). Titanium silicide has the advantages of simple formation processes and good stability at high temperature. As the sizes of MOSFET continually decrease, however, incomplete titanium silicide formation and phase transition can occur. More particularly, the so called narrow line width effect, i.e., the formation and phase transition of titanium silicide become more difficult as line width and contact area become smaller, not only causing the contact resistance and parasitic serial resistance to increase, but also result in unstable and unrepeatable characteristics from device to device, circuit to circuit, and wafer to wafer.

2) Cobalt Silicide Process

In order to deal with the line width effect at smaller device sizes, cobalt silicide emerges as a replacement of titanium silicide. The narrow line width effect, however, still occurs during the formation of cobalt silicide when device sizes further decrease. As the dopant depth of the source region continue to decrease, formation of cobalt silicide can also excessively consume the highly-doped silicon at the surface.

3) Nickel Silicide Process

Compared to titanium silicide and cobalt silicide, nickel silicide has a series of unique advantages. Nickel silicide still uses the two-step annealing process similar to the earlier silicides, but the annealing temperature is noticeably reduced (<600° C.). The lower annealing temperature would not result in diffusion of dopant ions in the silicide material, thus significantly reducing damages to the super-shallow junctions formed in the device. At the same time, the lower annealing temperature is beneficial to the integration of more advanced materials and technologies, including especially high-K dielectrics and metal gates. No narrow line width effect is discovered in the formation of nickel silicide even at line widths below 30 nanometers. The nickel silicide process also consumes relatively less silicon at the source/drain regions. Because the silicon near the surface happens to be the most highly doped regions, nickel silicide is very useful at reducing the overall contact resistance.

However, super-thin nickel silicide still faces a series of problems. On one hand, the commonly used low-resistance nickel silicide has a one-silicon-per-one-nickel chemical composition, i.e., nickel mono-silicide (NiSi). Because of the existence of silicon contacting the NiSi, as temperature increases, NiSi can react with Si, forming a more stable nickel di-silicide (NiSi₂) phase, i.e., the low resistance nickel silicide phase has latent instability at high temperature, setting a limit for a maximum temperature during subsequent processing steps. On the other hand, as the super-thin silicides become thinner and thinner, due to surface tension, a previously continuous and uniform film can become non-uniform in thickness and even discontinuous, causing the film to have a larger resistance or even non-conducting. Moreover, it is usually difficult to control the speed of silicide formation in typical nickel silicide formation processes, making it hard to form super-thin silicide layers.

Therefore, it is necessary to improve current methods of making metal-semiconductor-compound thin films.

### SUMMARY

The present invention purports to provide a metal-semiconductor-compound thin film, a DRAM storage unit including a metal-semiconductor-compound thin film, and its methods of making, so as to resolve the conflict between read/write speed of the transistor and storage capacity of the capacitor in a DRAM storage unit.

To solve the above problems, the present invention provides a metal-semiconductor-compound thin film, which is formed between a semiconductor layer and a polycrystalline semiconductor layer, to improve a contact between the semiconductor layer and the polycrystalline semiconductor layer. The metal-semiconductor-compound thin film has a thickness of about 2˜5 nm.

In one embodiment, the semiconductor layer is silicon or silicon-on-insulator, the polycrystalline semiconductor layer includes doped polysilicon, and the metal/semiconductor compound thin film includes a metal silicide.

In one embodiment, the semiconductor substrate is germanium or germanium-on-insulator, the polycrystalline semiconductor layer includes doped polycrystalline germanium, and the metal/semiconductor compound thin film includes a metal germanide.

In one embodiment, the metal/semiconductor compound thin film is formed by metal reacting with the semiconductor layer, where the metal can be any of nickel, cobalt, and titanium, or any of nickel, cobalt, and titanium with platinum incorporation.

In one embodiment, the metal is also incorporated with tungsten and/or molybdenum.

At the same time, in order to solve the above problems, the present invention further provides a DRAM storage cell, which includes a semiconductor substrate, and a MOS transistor and a capacitor formed on the semiconductor substrate. A source region of the MOS transistor is coupled to a bit line, its gate coupled to a word line, and its drain region coupled to the capacitor via a buffer layer. The buffer layer includes polycrystalline semiconductor. Between the drain region and the buffer layer there is a metal-semiconductor-compound thin film. The thickness of the metal-semiconductor-compound thin film is about 2˜5 nm.

In some embodiments, the semiconductor substrate is silicon or silicon-on-insulator, the polycrystalline semiconductor is doped polysilicon, and the metal-semiconductor-compound thin film includes a metal silicide.

In some embodiments, the semiconductor substrate is a germanium or germanium-on-insulator substrate, the polycrystalline semiconductor is doped polycrystalline germanium, and the metal-semiconductor-compound thin film includes a metal germanide.

In some embodiments, the metal-semiconductor-compound thin film is formed by chemical reaction between metal and a semiconductor layer at the drain region. The metal can be any of nickel, cobalt and titanium, or any of nickel, cobalt and titanium incorporated with platinum.

In some embodiments, the metal is further incorporated with tungsten and/or molybdenum.

At the same time, in order to solve the above problems, the present invention further provides a method of making a DRAM storage cell. The method comprises:
providing a semiconductor substrate, and forming a MOS transistor device on the semiconductor substrate;
forming a metal-semiconductor-compound thin film at a drain region of the MOS transistor device, the metal-semiconductor-compound thin film having a thickness of about 2˜5 nm;
forming a buffer layer on the metal-semiconductor-compound thin film; and forming a capacitor on the semiconductor substrate, the capacitor being coupled to the buffer layer.

In some embodiments, forming the metal-semiconductor-compound thin film at the drain region of the MOS transistor device further comprises:
depositing a layer of metal at the drain region of the MOS transistor device, the metal diffusing toward the drain region;
removing from a surface of the drain region a remaining portion of the layer of metal; and
performing annealing to form the metal-semiconductor-compound thin film at the drain region of the MOS transistor.

In some embodiments, the semiconductor substrate is at a temperature of 0˜300° C. during deposition of the layer of metal on the semiconductor substrate.

In some embodiments, the annealing is performed at a temperature of 200˜900° C.

In some embodiments, the semiconductor substrate is silicon or silicon-on-insulator substrate, the polycrystalline semiconductor is doped polysilicon, and the metal-semiconductor-compound thin film includes a metal silicide.

In some embodiments, the semiconductor substrate is a germanium or germanium-on-insulator substrate, the polycrystalline semiconductor is doped polycrystalline germanium, and the metal-semiconductor-compound thin film includes a metal germanide.

In some embodiments, the metal-semiconductor-compound thin film is formed by chemical reaction between metal and a semiconductor layer at the drain region. The metal can be any of nickel, cobalt and titanium, or any of nickel, cobalt and titanium incorporated with platinum.

In some embodiments, the metal is further incorporated with tungsten and/or molybdenum.

In some embodiments, the method further comprises coupling the source region of the MOS transistor to a bit line, and coupling a gate of the MOS transistor to a word line.

Compared with conventional techniques, the techniques in the above embodiments have the following advantages and positive results:
1) By adding a metal-semiconductor-compound thin film between the polycrystalline semiconductor layer and the semiconductor layer, contact resistance between the semiconductor layer and the polycrystalline semiconductor layer is reduced, resulting in enhanced contact performance.
2) By adding the metal-semiconductor-compound thin film between the drain region of the MOS transistor and the polycrystalline semiconductor buffer layer in the DRAM storage cell, contact resistance between the drain region and the polycrystalline semiconductor buffer layer is reduced, resulting in enhanced read/write speed of the transistor in the DRAM storage cell; at the same time, by controlling the thickness of the metal-semiconductor-compound thin film at about 2˜5 nm, excessive increase in drain leakage current between the drain region and the semiconductor substrate is avoided, preventing the capacitor from losing its stored charges too quickly. So, a refresh frequency of the DRAM cell is reduced.
3) In a DRAM storage cell made using the above method for making a DRAM storage cell, a metal-semiconductor-compound thin film is formed between the drain region of the MOS transistor device and a polycrystalline semiconductor buffer layer, and the thickness of the metal-semiconductor-compound thin film is controlled at about 2˜5 nm, resulting in enhanced performance of the DRAM storage cell.

### BRIEF DESCRIPTION OF THE DRAWINGS

FIG. 1 is a block diagram illustrating a contact between a semiconductor layer and a polycrystalline semiconductor layer according to embodiments of the present invention.

FIG. 2 is a flowchart illustrating a method of making a DRAM storage cell according to embodiments of the present invention.

### DETAILED DESCRIPTION OF THE EMBODIMENTS

A metal-semiconductor-compound thin film and a method of making a DRAM storage cell provided by embodiments of the present invention are described in more detail below with respect to the drawings. The advantages and characteristics of the present invention will become clearer according to the description below and the claims. It should be noted that the drawings use simplified form and inaccurate proportions, and should only be used to aid in easily and clearly describing the embodiments.

As a main idea of the present invention, a metal-semiconductor-compound thin film is formed between a semiconductor layer and a polycrystalline semiconductor layer, the metal-semiconductor-compound thin film having a thickness of about 2˜5 nm, so as to improve a contact between the semiconductor layer and the polycrystalline semiconductor layer. A DRAM storage cell is also provided. A metal-semiconductor-compound thin film is added between a drain region of a MOS transistor and a polycrystalline semiconductor buffer layer in the DRAM storage cell, and a thickness of the metal-semiconductor-compound thin film is controlled at about 2˜5 nm, so as to enhance a read/write speed of the transistor of the DRAM storage cell while excessive increase in a leakage current between the drain and a semiconductor substrate is prevented. A method for making a DRAM storage cell is also provided. A DRAM storage cell made using the method has a metal-semiconductor-compound thin film, with a thickness controlled at about 2˜5 nm, formed between a drain region of a MOS transitor and a polycrystalline semiconductor buffer layer, so as to enhance the performance of the DRAM storage cell.

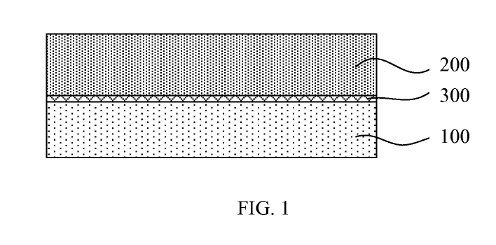

Reference is now made to FIG. 1, which is a block diagram of a contact between a semiconductor layer and a polycrystalline semiconductor layer according to embodiments of the present invention. As shown in FIG. 1, a metal-semiconductor-compound thin film 300 is formed between a semiconductor layer 100 and a polycrystalline semiconductor layer 200, so as to improve a contact between the semiconductor layer and the polycrystalline semiconductor layer. The metal-semiconductor-compound thin film has a thickness of about 2˜5 nm,

In one embodiment, the semiconductor layer 100 is silicon or silicon-on-insulator, the polycrystalline semiconductor layer 200 includes doped polysilicon, and the metal/semiconductor compound thin film 300 includes a metal silicide.

In one embodiment, the semiconductor layer 100 is germanium or germanium-on-insulator, the polycrystalline semiconductor layer 200 includes doped polycrystalline germanium, and the metal/semiconductor compound thin film 300 includes a metal germanide.

In one embodiment, the metal/semiconductor compound thin film 300 is formed from metal reacting with the semiconductor layer 100, where the metal can be any of nickel, cobalt, and titanium, or any of nickel, cobalt, and titanium with platinum incorporation.

In one embodiment, the metal is also incorporated with tungsten and/or molybdenum.

Embodiments of the present invention further provide a DRAM storage cell, which includes a semiconductor substrate, and a MOS transistor and a capacitor formed on the semiconductor substrate. A source region of the MOS transistor is coupled to a bit line, its gate coupled to a word line, and its drain region coupled to the capacitor via a buffer layer. The buffer layer includes polycrystalline semiconductor. A metal-semiconductor-compound thin film between the drain region and the buffer layer. A thickness of the metal-semiconductor-compound thin film is about 2˜5 nm.

By adding the metal-semiconductor-compound thin film between the drain region of the MOS transistor and the polycrystalline semiconductor buffer layer in the DRAM storage cell, while controlling the thickness of the metal-semiconductor-compound thin film at about 2˜5 nm, read/write speed of the transistor in the DRAM storage cell is enhanced while excessive increase in drain leakage current between the drain region and the semiconductor substrate is avoided.

In some embodiments, the semiconductor substrate is silicon or silicon-on-insulator substrate, the polycrystalline semiconductor is doped polysilicon, and the metal-semiconductor-compound thin film includes a metal silicide

In some embodiments, the semiconductor substrate is a germanium or germanium-on-insulator substrate, the polycrystalline semiconductor is doped polycrystalline germanium, and the metal-semiconductor-compound thin film includes a metal germanide

In some embodiments, the metal-semiconductor-compound thin film is formed by chemical reaction between metal and a semiconductor layer at the drain region. The metal can be any of nickel, cobalt and titanium, or any of nickel, cobalt and titanium incorporated with platinum

In some embodiments, the metal is further incorporated with tungsten and/or molybdenum

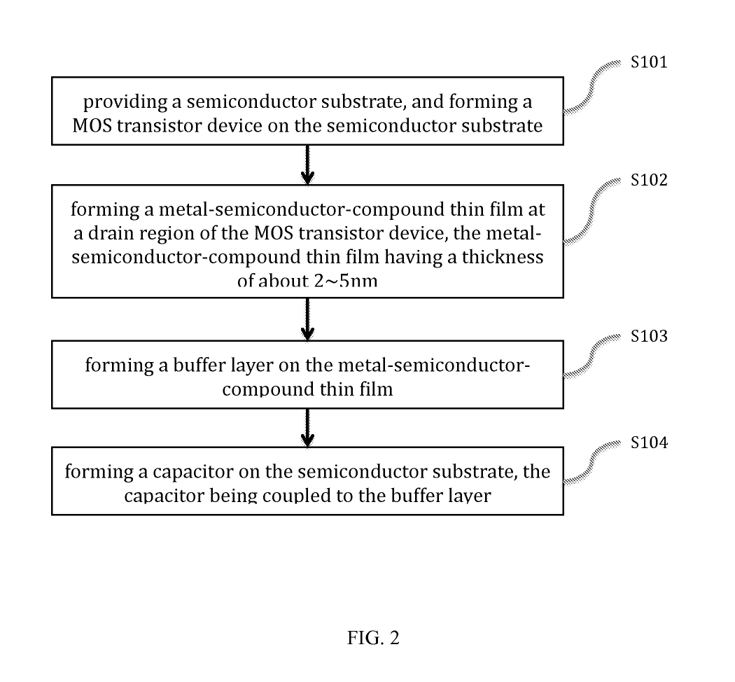

Reference now is made to FIG. 2, which is a flowchart illustrating a method of making a DRAM storage cell according to embodiments of the present invention. As shown in FIG. 2, a method of making a DRAM storage cell, as provided by embodiments of the present invention, comprises the following steps.

Step 101—A semiconductor substrate is provided, and a MOS transistor device is formed on the semiconductor substrate. More specifically, forming a MOS transistor device on the semiconductor substrate comprises: forming a gate stack layer on the semiconductor substrate, and forming a gate electrode using photolithography and etching. Afterwards, doping by ion implantation is used to form source and drain regions. The gate stack layer includes polysilicon, and a metal silicide and an insulator layer formed consecutively on the polysilicon.

Step 102—A metal-semiconductor-compound thin film is formed at the drain region of the MOS transistor device. The metal-semiconductor-compound thin film has a thickness of about 2˜5 nm.

S103—A buffer layer is formed on the metal-semiconductor-compound thin film. Specifically, the buffer layer includes a polycrystalline semiconductor layer.

S104—A capacitor is formed on the semiconductor substrate, the capacitor being coupled to the buffer layer. Specifically, the capacitor is a MIM capacitor.

In a DRAM storage cell made using the above method for making a DRAM storage cell, a metal-semiconductor-compound thin film is formed between the drain region of the MOS transistor device and a polycrystalline semiconductor buffer layer, and the thickness of the metal-semiconductor-compound thin film is controlled at about 2˜5 nm, whereby read/write speed of the transistor in the DRAM storage cell is enhanced while excessive increase in drain leakage current between the drain region and the semiconductor substrate is avoided.

In further embodiments, forming a metal-semiconductor-compound thin film at the drain region of the MOS transistor device comprises:
depositing a layer of metal at the drain region of the MOS transistor device, the metal diffusing toward the drain region;
removing from a surface of the drain region a remaining portion of the layer of metal; and
performing annealing to form the metal-semiconductor-compound thin film at the drain region of the MOS transistor.

Because there is a certain degree of saturation when metal is diffusing into the semiconductor substrate, the thickness of the metal-semiconductor-compound thin film formed using the above method is controllable (i.e., the eventually formed metal-semiconductor-compound thin film has a certain thickness.) The metal-semiconductor-compound thin film is made super-thin for the benefit of enhancing the performance of the DRAM storage cell.

In further embodiments, the semiconductor substrate is at a temperature of 0˜300° C. when the layer of metal is being deposited on the semiconductor substrate.

In further embodiments, the annealing is performed at a temperature of 200˜900° C.

In further embodiments, the semiconductor substrate is silicon or silicon-on-insulator substrate, the polycrystalline semiconductor is doped polysilicon, and the metal-semiconductor-compound thin film includes a metal silicide

In further embodiments, the semiconductor substrate is germanium or germanium-on-insulator substrate, the polycrystalline semiconductor is doped polycrystalline germanium, and the metal-semiconductor-compound thin film includes a metal germanide.

In further embodiments, the metal-semiconductor-compound thin film is formed by chemical reaction between metal and a semiconductor layer at the drain region. The metal can be any of nickel, cobalt and titanium, or any of nickel, cobalt and titanium incorporated with platinum. The platinum is incorporated because pure nickel silicide has poor stability at higher temperature, or tends to become non-uniform and agglomerate, or forms nickel di-silicide (NiSi₂), which has a high resistivity, seriously affecting device performance. Therefore, in order to slow down the formation of nickel silicide and prevent agglomeration and nickel di-silicide formation at high temperature, nickel is incorporated with platinum by a certain ratio. Platinum incorporation for other metals can be similarly explained.

In further embodiments, the metal is further incorporated with tungsten and/or molybdenum, so as to further control the formation of nickel silicide or platinum incorporated nickel silicide and the diffusion of nickel/platinum.

In further embodiments, the method further comprises coupling the source region of the MOS transistor to a bit line, and coupling the gate of the MOS transistor to a word line.

In summary, the present invention provides a metal-semiconductor-compound thin film, formed between a semiconductor layer and a polycrystalline semiconductor layer, the metal-semiconductor-compound thin film having a thickness of about 2˜5 nm, so as to improve a contact between the semiconductor layer and the polycrystalline semiconductor layer. A DRAM storage cell is also provided. A metal-semiconductor-compound thin film is added between a drain region of a MOS transistor and a polycrystalline semiconductor buffer layer in the DRAM storage cell, and a thickness of the metal-semiconductor-compound thin film is controlled at about 2˜5 nm, so as to enhance read/write speed of the transistor of the DRAM storage cell while excessive increase in a leakage current between the drain and a semiconductor substrate is prevented. A method for making a DRAM storage cell is also provided. A DRAM storage cell made using the method has a metal-semiconductor-compound thin film, with a thickness controlled at about 2˜5 nm, formed between a drain region of its MOS transitor and a polycrystalline semiconductor buffer layer, so as to enhance the performance of the DRAM storage cell.

It is obvious that those skilled in the art can make various changes and modification of the present invention without departing from the spirit and scope of the present invention. Thus, the present invention intends to include such changes and modifications if such changes and modifications belong to the technology scope of the claims and their equivalents.

We claim:

1. A metal-semiconductor-compound thin film formed between a semiconductor layer and a polycrystalline semiconductor layer, to improve a contact between the semiconductor layer and the polysilicon layer, characterized in that the metal-semiconductor-compound thin film has a thickness of 2˜5 nm.

2. The metal-semiconductor-compound thin film of claim 1, characterized in that the semiconductor layer is silicon or silicon-on-insulator, the polycrystalline semiconductor layer includes doped polysilicon, and the metal/semiconductor compound thin film includes a metal silicide.

3. The metal-semiconductor-compound thin film of claim 1, characterized in that the semiconductor layer is germanium or germanium-on-insulator, the polycrystalline semiconductor layer includes doped polycrystalline germanium, and the metal/semiconductor compound thin film includes a metal germanide.

4. The metal-semiconductor-compound thin film of claim 2 or 3, characterized in that the metal/semiconductor compound thin film is formed by metal reacting with the semiconductor layer, where the metal can be any of nickel, cobalt, and titanium, or any of nickel, cobalt, and titanium with platinum incorporation.

5. The metal-semiconductor-compound thin film of claim 4, characterized in that the metal is further incorporated with tungsten and/or molybdenum.

6. A DRAM storage cell, comprising a semiconductor substrate, and a MOS transistor and a capacitor formed on the semiconductor substrate, a source region of the MOS transistor being coupled to a bit line, a gate coupled to a word line, and a drain region coupled to the capacitor via a buffer layer, the buffer layer including polycrystalline semiconductor, characterized in that a metal-semiconductor-compound thin film is formed between the drain region and the buffer layer, a thickness of the metal-semiconductor-compound thin film being about 2˜5 nm.

7. The DRAM cell of claim 6, characterized in that the semiconductor substrate is silicon or silicon-on-insulator, the polycrystalline semiconductor layer includes doped polysilicon, and the metal/semiconductor compound thin film includes a metal silicide.

8. The DRAM cell of claim 6, characterized in that the semiconductor substrate is germanium or germanium-on-insulator, the polycrystalline semiconductor layer includes doped polycrystalline germanium, and the metal/semiconductor compound thin film includes a metal germanide.

9. The DRAM cell of claim 7 or 8, characterized in that the metal/semiconductor compound thin film is formed by metal reacting with the semiconductor layer of the drain region, where the metal can be any of nickel, cobalt, and titanium, or any of nickel, cobalt, and titanium with platinum incorporation.

10. The DRAM cell of claim 9, characterized in that the metal is further incorporated with tungsten and/or molybdenum.

11. A method of making a DRAM storage cell, characterized in that the method comprises:
providing a semiconductor substrate, and forming a MOS transistor device on the semiconductor substrate;
forming a metal-semiconductor-compound thin film at a drain region of the MOS transistor device, the metal-semiconductor-compound thin film having a thickness of about 2˜5 nm;
forming a buffer layer on the metal-semiconductor-compound thin film; and
forming a capacitor on the semiconductor substrate, the capacitor being coupled to the buffer layer.

12. The method of making a DRAM cell according to claim 11, characterized in that forming the metal-semiconductor-compound thin film at the drain of the MOS transistor device further comprises:
depositing a layer of metal at the drain region of the MOS transistor device, the metal diffusing toward the drain region;
removing from a surface of the drain region a remaining portion of the layer of metal; and
performing annealing to form the metal-semiconductor-compound thin film at the drain region of the MOS transistor.

13. The method of making a DRAM cell according to claim 12, characterized in that the semiconductor substrate is at a temperature of 0˜300° C. during deposition of the layer of metal on the drain region.

14. The method of making a DRAM cell according to claim 13, characterized in that the annealing is performed at a temperature of 200˜900° C.

15. The method of making a DRAM cell according to claim 12, characterized in that the semiconductor substrate is silicon or silicon-on-insulator, the polycrystalline semiconductor is doped polysilicon and the metal/semiconductor compound thin film includes a metal silicide.

16. The method of making a DRAM cell according to claim 11, characterized in that the semiconductor substrate is a germanium or germanium-on-insulator substrate, the polycrystalline semiconductor is doped polycrystalline germanium, and the metal-semiconductor-compound thin film includes a metal germanide.

17. The method of making a DRAM cell according to claim 15 or 16, characterized in that the metal-semiconductor-compound thin film is formed by chemical reaction between metal and a semiconductor layer at the drain region. The metal can be any of nickel, cobalt and titanium, or any of nickel, cobalt and titanium incorporated with platinum.

18. The method of making a DRAM cell according to claim 17, characterized in that the metal is also incorporated with tungsten and/or molybdenum.

19. The method of making a DRAM cell according to claim 11, characterized in that the method further comprises coupling the source region of the MOS transistor to a bit line, and coupling a gate of the MOS transistor to a word line.
